(19) United States
(12) Patent Application Publication
(10) Pub. No.: US 2017/0241009 A1
(43) Pub. Date: Aug. 24, 2017

(54) COATED ARTICLE INCLUDING METAL ISLAND LAYER(S) FORMED USING STOICHIOMETRY CONTROL, AND/OR METHOD OF MAKING THE SAME

(71) Applicant: Guardian Industries Corp., Auburn Hills, MI (US)

(72) Inventors: Brent BOYCE, Novi, MI (US); Yiwei LU, Ann Arbor, MI (US)

(21) Appl. No.: 15/051,927

(22) Filed: Feb. 24, 2016

(51) Int. Cl. C23C 14/18; C23C 14/34; C23C 14/58; C23C 14/02

(52) U.S. Cl. CPC C23C 14/185; C23C 14/021; C23C 14/3464; C23C 14/3435; C23C 14/5806

(57) ABSTRACT

Certain example embodiments relate to techniques for improving the uniformity of, and/or conformance to a desired pattern for, metal island layers (MILs) formed on a substrate (e.g., a glass or other substrate), and/or associated products. Certain example embodiments form MILs using a laser or other energy source or magnetic field assisted technique, e.g., to compensate for non-uniformities that otherwise likely would result in the MIL diverging from its desired configuration. For example, a laser or other energy source may introduce heat onto a substrate, enable pulsed laser deposition, raster a target including the MIL metal to be deposited, raster a substrate where the MIL is to be formed, etc. These and/or other techniques may be used to enable the MIL to be formed on the substrate in a desired pattern, e.g., by compensating for implicit non-uniformities of the substrate and/or by selectively creating non-uniformities in how the MIL is formed.

### FIELD OF THE INVENTION

Certain example embodiments of this invention relate to coated articles including metal island layer(s), and/or methods of making the same. More particularly, certain example embodiments of this invention relate to techniques for improving the uniformity of, and/or conformance to a desired pattern for, metal island layer(s) formed on a substrate (e.g., a glass or other transparent substrate), and/or associated products.

### BACKGROUND AND SUMMARY OF EXAMPLE EMBODIMENTS OF THE INVENTION

At the interface between a pair of conductive and non-conductive materials, there exist electronic states that interact with light in ways unlike bulk dielectric or metal optical interaction. These states are known as surface plasmons. Metal Island Layers (MILs) are known in the art and make use of surface plasmon (SP) effects.

MILs generally involve a discontinuous, or continuous and interrupted, layer of a so-called inert or noble metal disposed on a transparent substrate (such as, for example, a glass substrate). Gold oftentimes is used as the conductive noble metal, although silver, copper, and/or other metals may be used in place of gold in different cases. Inert or noble metals oftentimes are preferred for durability reasons, and because high conductivity is believed to generate stronger plasmons. FIG. 1 is a schematic view of a metal island layer 104 on a substrate 102. The metal islands 106a-106e are spaced apart, and the extensions therefrom represent the surface plasmons.

By using controlled SP effects, MILs at least in theory can allow for novel optical properties to be achieved, while circumventing classical absorption approaches. That is, by creating a large dielectric/metal area via formation of MILs, unique optical effects at least in theory can be achieved with highly tunable optical characteristics related to, for example, the geometry of islands, the optical and conductive nature of the island material, and the optical nature of surrounding dielectric materials. Coloration, for instance, typically depends on the length, width, height, and density of the metal islands, as well as the conductivity of the material. The coloration of such coated articles tends to be less angularly dependent than coated articles formed using bulk materials.

One advantage of this approach, and in contrast with classical absorptive layers, is that it utilizes relatively thin layers of material (i.e., the material in the MIL) and thus lends itself to high volume and/or high speed manufacturing processes that otherwise might be cost prohibitive for thick or slowly deposited materials.

For instance, it will be appreciated that absorptive-like effects at least in theory could be implemented via sputter deposition in an economical way. In this regard, early stage thin film growth from a continuous deposition flux is known to proceed from initial island formation until a percolation limit is reached. Islands connect at the percolation limit, forming an interconnected but sub-continuous layer, until a continuous layer ultimately is formed. MILs thus in theory could be formed faster than continuous layers using sputtering techniques.

Unfortunately, however, it oftentimes is difficult to control MIL formation on substrates, e.g., through conventional sputter deposition techniques. The detailed nature of island formation and thus island dimensions is a sensitive function of substrate temperature, substrate morphology, chemical interaction between the surface material and the deposited species, and kinetic energy of the deposited species. Because of the sensitivity of MILs to surface conditions, chemical interactions, energy fluxes, etc., the inventors have observed that MILs typically form non-uniformly, or differently from desired patterns, especially when attempts are made to scale beyond laboratory-scale dimensions. For instance, scaling becomes difficult beyond even 4 square inch laboratory experiments.

Thus, it will be appreciated that it would be desirable to develop improved techniques for forming MILs, e.g., to make coated articles with novel optical properties in a fast, cost-effective manner, where the MIL formation conforms to a highly uniform and/or desired pattern.

In certain example embodiments, there is provided a method of making a coated article comprising a metal island layer supported by a substrate. The substrate has a surface to be coated. Local surface stoichiometry at one or more areas of the surface to be coated is selectively modified. The metal island layer is formed, directly or indirectly, on the surface of the substrate in a desired pattern defined, at least in part, as a result of the selective modifying.

In certain example embodiments, a method of making a coated article comprising a substrate having a surface to be coated is provided. A layer comprising a plurality of islands is formed on the surface to be coated in making the coated article. First and second targets that are different from one another are co-sputtered. The sputtering of material is selectively adjusted, using a laser, to adjust chemical interactions taking place at the surface to be coated in forming the layer comprising islands on the substrate. Each of the islands comprises metal, the islands collectively creating a surface plasmon effect the causes the coated article to have a desired optical appearance.

Coated articles made by the techniques disclosed herein also are contemplated.

The features, aspects, advantages, and example embodiments described herein may be combined to realize yet further embodiments.

### BRIEF DESCRIPTION OF THE DRAWINGS

These and other features and advantages may be better and more completely understood by reference to the following detailed description of exemplary illustrative embodiments in conjunction with the drawings, of which:

FIG. 1 is a schematic view of a metal island layer on a substrate;

FIG. 2 is a graph showing how intrinsic non-uniformities can be compensated for in order to obtain desired island formation, in accordance with certain example embodiments;

FIG. 3 helps demonstrate how a laser or other energy source can be used to print a thermal pattern on a substrate and therefore affect island formation, in accordance with certain example embodiments;

FIG. 4 helps demonstrate how a laser or other energy source or magnetic field can be used to control surface stoichiometry and therefore affect island formation, in accordance with certain example embodiments;

FIG. 5 helps demonstrate how a laser or other energy source or magnetic field can be used to control material stoichiometry by rastering over or otherwise affecting one or more targets and therefore affect island formation, in accordance with certain example embodiments; and

FIG. 6 is a flowchart illustrating a process for forming a metal island layer on a substrate in accordance with certain example embodiments.

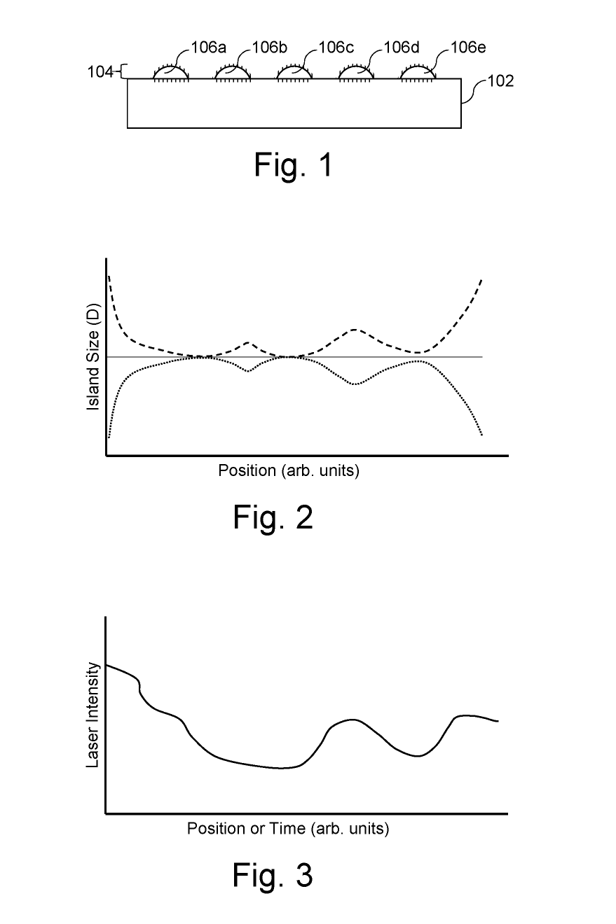

### DETAILED DESCRIPTION OF EXAMPLE EMBODIMENTS OF THE INVENTION

Certain example embodiments relate to techniques for improving the uniformity of, and/or conformance to a desired pattern for, metal island layers (MILs) formed on a substrate (e.g., a glass or other transparent substrate), and/or associated products. Certain example embodiments form MILs using a laser or other energy source or magnetic field assisted technique, e.g., to compensate for non-uniformities that otherwise likely would result in the MIL diverging from its desired configuration. For example, as will be appreciated from the description below, a laser or other energy source may be used to introduce heat onto a substrate, enable pulsed laser deposition, raster a target that includes the MIL metal to be deposited, raster a substrate where the MIL is to be formed, and/or the like. Similarly, magnetic fields can be used to create localized effects that influence, in part, MIL formation on a substrate. In this regard, it is possible to achieve a high degree of control of magnetic fields (and thus material formation) using tunable sputtering magnet bars, and magnetic bars or other means of controlling magnetic fields may be used to control substrate uniformity to create a desired MIL pattern. These and/or other techniques may be used to enable the MIL to be formed on the substrate in a desired pattern.

FIG. 2 is a graph showing how intrinsic non-uniformities can be compensated for in order to obtain desired island formation, in accordance with certain example embodiments. The solid line in FIG. 2 represents desired island formation. For the purposes of this example, there is a desire for island size (D) to be constant across the substrate. The dashed line in FIG. 2 represents how intrinsic non-uniformities would affect the island size as a function of position on the substrate. The dotted line in FIG. 2 is the inverse of the dashed line. In order to obtain the island size distribution desired (which as noted above is uniform in this example), the MIL formation process may be controlled to in essence create the profile represented by the dotted line. In other words, the dashed line shows the impact of surface condition, chemical interaction, energy flux, and/or other non-uniformities, on island formation.

As will be appreciated by those skilled in the art, the MIL growth can be affected by the kinetic energy of the adatoms forming the islands, the substrate temperature, chemical interactions with respect to the material(s) being deposited and the substrate and/or targets used, and surface roughness. The inventors have realized that the kinetic energy and roughness factors typically are controlled or controllable via the MIL formation apparatus (e.g., the sputtering apparatus and/or process parameters used therewith). Thus, certain example embodiments focus on improving uniformity and/or conformance to a desired pattern by primarily targeting one or more of the above-described and/or other factors. It will be appreciated, however, that certain example embodiments may also seek to influence MIL formation via kinetic energy and/or surface roughness adjustments in addition to, or in place of, these primary sources of non-uniformities.

Although certain example embodiments reference the creation of uniform MIL layers, it will be appreciated that non-uniformities in different areas of the substrate may be desired in some instances. For instance, certain example embodiments may be used to simulate tinted glass, and/or other color control applications. In such cases, high uniformity of MIL formation across the entire viewing area may be desired. As another example, the example techniques disclosed herein may be used to create patterns for applications such as, for example, polarizing effects; signage; conductive pathways for photovoltaic, electrochromic or other electronics applications; bird friendly glass; logos; and/or the like. In such cases, strong delineation between areas of MIL formation and non-formation may be desired, and the techniques disclosed herein may be used to facilitate such the creation of the relevant pattern(s). As still another example, the techniques disclosed herein may be used to help control how the coating interacts with light as a function of angle of incidence relative to the substrate. In this regard, in some cases, the techniques disclosed herein may be used to reduce angular dependency (e.g., to help provide the same or substantially the same color at all angles), whereas the techniques disclosed herein may be used to enhance angular dependency (e.g., to help block light at certain angles such as from the sun high in the sky) in other cases. The effect may depend on the specific MIL configuration including length, width, height, density, and orientation, and MIL formation may be customized using the techniques described herein to realize advantageous combinations of these factors.

As a first example, fine control of surface conditions, in this case local surface temperature, and therefore island geometry and optical properties, may be achieved through laser or other energy source scanning of the substrate. FIG. 3 helps demonstrate how a laser or other energy source can be used to print a thermal pattern on a substrate and therefore affect island formation, in accordance with certain example embodiments. That is, FIG. 3 shows how laser or other energy source intensity can be varied over the position of the substrate (and/or with respect to time). This allows for selective location temperature control by controlling the laser intensity as a function of laser spot position.

The type of laser used to increase temperature may be based on, for example, how it interacts with the substrate (or layers on the substrate) of choice, e.g., in order to provide for good temperature control. The laser focus size and/or shape, as well as the wavelengths, may be selected on this basis. The thermal conductivity of the surface(s) being heated also may be taken into account. For instance, the more thermally conductive the surface(s) being heated, the more finely sized (smaller) the laser may be, to provide for fine adjustments. Where strong delineation between areas where MIL islands are formed and are not formed, lower thermal conductivity substrates and/or layers may be desirable.

As a second example, stoichiometry may be locally tuned to affect island geometry and optical properties. For instance, local surface stoichiometry may be achieved by modifying the substrate and/or one or more previously formed layers thereon, e.g., the substrate itself and/or one or more thin film layers on which the MIL is to be directly or indirectly formed. This may be accomplished using a laser, ion beam, adjusting a magnetic field (e.g., using tunable magnet bars and/or the like), or other technique. The layer to be modified may be, for example, a thin film layer such as, for example, a silicon-inclusive layer (e.g., of or including silicon oxide, silicon nitride, or silicon oxynitride) used for blocking sodium migration, optical purposes, and/or the like). A layer comprising zinc oxide and/or the like also may be used for these and/or other similar purposes. In certain example embodiments, a thin film leveling layer may be formed on the substrate, e.g., to decrease surface roughness and/or other irregularities, etc.

Alternatively, or in addition, a laser, ion beam, or other technique may be used to locally control stoichiometry in connection with one or more sputtering targets during MIL formation. Spatially non-uniform stoichiometry may be achieved, for example, through laser-modified sputtering, ion beam assisted deposition, magnetic field control, and/or the like.

Laser-modified sputtering may be used, for example, where two materials, X and Y, are co-sputtered and the exact composition at the substrate XY is tuned using laser enhancement of the sputtering of one or both of the two materials (X and/or Y). The materials X and Y can be chosen to enhance (or diminish) as desired the chemical interaction between the substrate (and/or layer(s) thereon) and the metal island layer and therefore modify the formation of metal islands. In certain example embodiments, this may be facilitated by using two different materials that have poor inter-diffusivity.

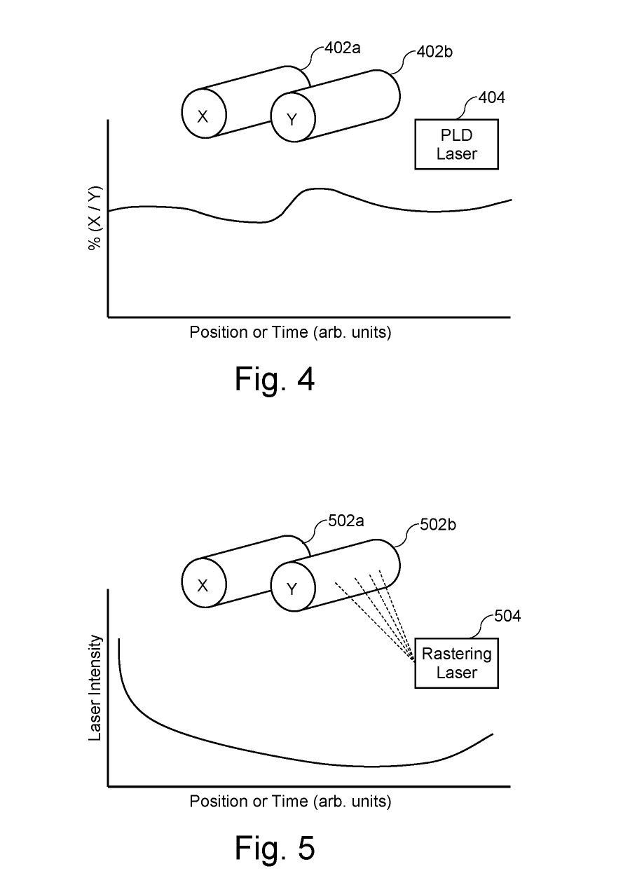

FIG. 4 helps demonstrate how a laser or other energy source or magnetic field can be used to control surface stoichiometry and therefore affect island formation, in accordance with certain example embodiments, and FIG. 5 helps demonstrate how a laser or other energy source or magnetic field can be used to control material stoichiometry by rastering over or otherwise affecting one or more targets and/or the substrate itself (and/or layers formed thereon) and therefore affect island formation, in accordance with certain example embodiments. It will be appreciated that rastering across a target with material to be modified will typically result in more of this material being deposited. It will be appreciated that PLD, laser rastering, and/or other similar techniques may be used in connection with the MIL metal target only, with another material, with the substrate itself, with layers on the substrate, etc. Magnetic field control also may be used to control MIL formation in a desired pattern, e.g., as magnetic fields may be controlled using tuning bars and/or the like.

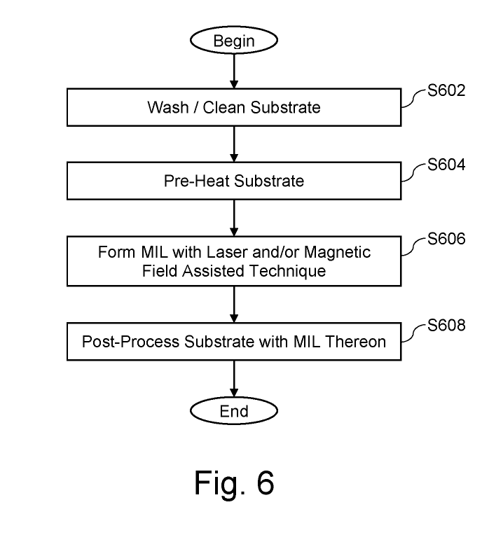

FIG. 6 is a flowchart illustrating a process for forming a metal island layer on a substrate in accordance with certain example embodiments. The substrate on which the MIL is to be formed is washed and/or otherwise cleaned in step S602. This may include rinsing with de-ionized water, plasma ashing, etc. The substrate may be pre-heated in step S604, e.g., to precondition the substrate and remove gross-level non-uniformities prior to MIL formation. This may be accomplished, for example, using equilibrium-type heating including, for example, a furnace or the like. The pre-heating temperature preferably is greater than room temperature. It also preferably is less than 300 degrees C., more preferably less than 250 degrees C. The exact temperature may be tuned, recognizing that a temperature that is too low will result in islands unsuitable (e.g., too small) for the effect, whereas a temperature that is too high may result in a continuous layer and, thus, not a metal island layer.

The MIL may be formed using a laser or other energy source and/or a magnetic field adjusted technique in step S606. That is, certain example embodiments may use a laser or other energy source and/or controlled magnetic field in some cases to change the surface temperature, alter the stoichiometry of material(s) provided on the substrate and/or the substrate itself prior to MIL formation, alter the stoichiometry of the target including the MIL metal material and/or a material co-sputtered with the MIL metal material, the manner in which the material is removed from the substrate and/or formed on the substrate, and/or the like. The MIL itself may be formed by sputtering, e.g., up to the percolation limit or other desired level where islands are preferentially formed in a desired pattern. The size of the islands may vary based on the application. However, an average size distribution of 3-25 nm in major diameter or distance, more preferably 5-15 nm in major diameter or distance, and for example about 10 nm (+/−10% or 15%) will be suitable for most applications. In other cases, an average size distribution of up to about 1,000 nm in major diameter or distance may be appropriate depending on the desired effect, with an average size distribution of 100-300 nm in major diameter or distance (+/−10% or 15%) being another example range that may be used in a wide variety of different applications.

As indicated above, these techniques may be used separately, in combination, or in any combination of sub-combinations. For example, these techniques may be used in-line, with modification of the substrate (via temperature and/or stoichiometry) first, etc.

Post-processing of the substrate may take place in step S608. This may include, for example, protecting the formed MIL with an overcoat layer (e.g., a layer comprising silicon such as, for example, silicon oxide, silicon nitride, silicon oxynitride; a layer comprising zirconium oxide; and/or the like). It also may include cutting, seeming, shipping, heat treating (e.g., heat strengthening and/or thermal tempering), etc.

It will be appreciated that the MIL may be incorporated into a functional layer stack such as, for example, a low-emissivity coating, an anti-reflective coating, etc.

Certain example embodiments have been described in connection with sputtering. It will be appreciated, however, that other forms of physical vapor deposition may be used in different example embodiments.

It will be appreciated that the MILs of certain example embodiments may be formed to be of or include inert or noble metals such as, for example, ruthenium, rhodium, palladium, silver, osmium, iridium, platinum, mercury, rhenium, copper, and/or gold.

Although certain example embodiments have been described as including glass substrates, it will be appreciated that other types of transparent substrates may be used in different example embodiments. In addition, although certain applications have been described, it will be appreciated that the techniques disclosed herein may be used in connection with a variety of commercial and/or residential window, spandrel, merchandizer, signage, electronic device, and/or other applications. Such applications may be monolithic, laminated, and/or involve insulating glass (IG), vacuum insulating glass (VIG), and/or other types of units and/or arrangements.

The terms “heat treatment” and “heat treating” as used herein mean heating the article to a temperature sufficient to achieve thermal tempering and/or heat strengthening of the glass-inclusive article. This definition includes, for example, heating a coated article in an oven or furnace at a temperature of at least about 550 degrees C., more preferably at least about 580 degrees C., more preferably at least about 600 degrees C., more preferably at least about 620 degrees C., and most preferably at least about 650 degrees C. for a sufficient period to allow tempering and/or heat strengthening. This may be for at least about two minutes, up to about 10 minutes, up to 15 minutes, etc., in certain example embodiments.

As used herein, the terms “on,” “supported by,” and the like should not be interpreted to mean that two elements are directly adjacent to one another unless explicitly stated. In other words, a first layer may be said to be “on” or “supported by” a second layer, even if there are one or more layers therebetween.

In certain example embodiments, there is provided a method of making a coated article comprising a metal island layer supported by a substrate. The substrate has a surface to be coated. Local surface stoichiometry at one or more areas of the surface to be coated is selectively modified. The metal island layer is formed, directly or indirectly, on the surface of the substrate in a desired pattern defined, at least in part, as a result of the selective modifying.

In addition to the features of the previous paragraph, in certain example embodiments, the desired pattern may be a substantially uniform pattern for the metal island layer.

In addition to the features of either of the previous two paragraphs, in certain example embodiments, the coated article may simulate tinted glass.

In addition to the features of any of the three previous paragraphs, in certain example embodiments, the selective modifying may delineate, at least in part, a first area where the metal island layer is to be formed and a second area where the metal island layer is not to be formed, e.g., with the first and second areas conforming to the desired pattern.

In addition to the features of any of the four previous paragraphs, in certain example embodiments, the coated article may have an optically visible appearance, in conformance with the desired pattern, created by a surface plasmon effect of the metal island layer.

In addition to the features of any of the five previous paragraphs, in certain example embodiments, prior to the exposing, the substrate may be pre-heated to a temperature greater than room temperature and less than 300 degrees C.

In addition to the features of any of the six previous paragraphs, in certain example embodiments, islands of the metal island layer may have an average size distribution of 5-15 nm or 100-300 nm in diameter or major distance.

In addition to the features of any of the seven previous paragraphs, in certain example embodiments, the metal island layer may comprise a continuous but interrupted layer of islands formed from a noble or inert metal.

In addition to the features of any of the eight previous paragraphs, in certain example embodiments, the substrate may be a glass substrate.

In addition to the features of any of the nine previous paragraphs, in certain example embodiments, the selective modifying may be performed by scanning a laser across the surface to be coated.

In addition to the features of any of the 10 previous paragraphs, in certain example embodiments, a sputtering target may be the source metal in the metal island layer.

In addition to the features of any of the 11 previous paragraphs, in certain example embodiments, the forming of the metal island layer and the selective modifying may include co-sputtering from first and second targets that are different from one another, and using a laser to enhance sputtering of material from exactly one of the first and second targets.

In addition to the features of the previous paragraph, in certain example embodiments, the use of the laser to enhance the sputtering may enhance chemical interaction between the surface to be coated and the metal island layer.

In addition to the features of any of the 13 previous paragraphs, in certain example embodiments, the surface to be coated may be a major surface of the substrate.

In addition to the features of any of the 14 previous paragraphs, in certain example embodiments, a thin film coating may be formed directly or indirectly on the substrate, and the surface to be coated may be a major surface of the thin film coating.

In certain example embodiments, a method of making a coated article comprising a substrate having a surface to be coated is provided. A layer comprising a plurality of islands is formed on the surface to be coated in making the coated article. First and second targets that are different from one another are co-sputtered. The sputtering of material is selectively adjusted, using a laser, to adjust chemical interactions taking place at the surface to be coated in forming the layer comprising islands on the substrate. Each of the islands comprises metal, the islands collectively creating a surface plasmon effect the causes the coated article to have a desired optical appearance.

In addition to the features of the previous paragraph, in certain example embodiments, the selective adjusting may include focusing the laser on exactly one of the first and second targets.

In addition to the features of the previous paragraph, in certain example embodiments, the selective adjusting may enhance the sputtering of the material on which the laser is focused.

In certain example embodiments, there is provided a coated article made by the method of any of the previous 18 paragraphs.

While the invention has been described in connection with what is presently considered to be the most practical and preferred embodiment, it is to be understood that the invention is not to be limited to the disclosed embodiment, but on the contrary, is intended to cover various modifications and equivalent arrangements included within the spirit and scope of the appended claims.

What is claimed is:

1. A method of making a coated article comprising a metal island layer supported by a substrate, the substrate having a surface to be coated, the method comprising:
selectively modifying local surface stoichiometry at one or more areas of the surface to be coated; and
forming the metal island layer, directly or indirectly, on the surface of the substrate in a desired pattern defined, at least in part, as a result of the selective modifying.

2. The method of claim 1, wherein the desired pattern is a substantially uniform pattern for the metal island layer.

3. The method of claim 2, wherein the coated article simulates tinted glass.

4. The method of claim 1, wherein the selective modifying delineates, at least in part, a first area where the metal island layer is to be formed and a second area where the metal island layer is not to be formed, the first and second areas conforming to the desired pattern.

5. The method of claim 1, wherein the coated article has an optically visible appearance, in conformance with the desired pattern, created by a surface plasmon effect of the metal island layer.

6. The method of claim 1, further comprising prior to the exposing, pre-heating the substrate to a temperature greater than room temperature and less than 300 degrees C.

7. The method of claim 1, wherein islands of the metal island layer have an average size distribution of 5-15 nm or 100-300 nm in diameter or major distance.

8. The method of claim 1, wherein the metal island layer comprises a continuous but interrupted layer of islands formed from a noble or inert metal.

9. The method of claim 1, wherein the substrate is a glass substrate.

10. The method of claim 1, wherein the selective modifying is performed by scanning a laser across the surface to be coated.

11. The method of claim 1, wherein a sputtering target is the source metal in the metal island layer.

12. The method of claim 1, wherein the forming of the metal island layer and the selective modifying include co-sputtering from first and second targets that are different from one another, and using a laser to enhance sputtering of material from exactly one of the first and second targets.

13. The method of claim 12, wherein the use of the laser to enhance the sputtering enhances chemical interaction between the surface to be coated and the metal island layer.

14. The method of claim 1, wherein the surface to be coated is a major surface of the substrate.

15. The method of claim 1, further comprising forming a thin film coating directly or indirectly on the substrate, wherein the surface to be coated is a major surface of the thin film coating.

16. A method of making a coated article comprising a substrate having a surface to be coated, a layer comprising a plurality of islands being formed on the surface to be coated in making the coated article, the method comprising:
co-sputtering first and second targets that are different from one another; and
selectively adjusting the sputtering of material, using a laser, to adjust chemical interactions taking place at the surface to be coated in forming the layer comprising islands on the substrate,
wherein each of the islands comprises metal, the islands collectively creating a surface plasmon effect the causes the coated article to have a desired optical appearance.

17. The method of claim 16, wherein the selective adjusting includes focusing the laser on exactly one of the first and second targets.

18. The method of claim 17, wherein the selective adjusting enhances the sputtering of the material on which the laser is focused.

19. A coated article made by the method of claim 1.

20. A coated article made by the method of claim 16.
